(19) United States
(12) Patent Application Publication
(10) Pub. No.: US 2015/0187307 A1
(43) Pub. Date: Jul. 2, 2015

(54) TFT ARRAY SUBSTRATE AND DISPLAY APPARATUS

(71) Applicants: Shanghai AVIC Optoelectronics Co., Ltd., Shanghai (CN); Tianma Micro-Electronics Co., Ltd., Shenzhen (CN)

(72) Inventors: Huijun Jin, Shanghai (CN); Yao Lin, Shanghai (CN)

(21) Appl. No.: 14/306,665

(22) Filed: Jun. 17, 2014

(30) Foreign Application Priority Data
Dec. 31, 2013 (CN) 201310754423.8

(51) Int. Cl. G09G 3/36; H01L 27/12

(52) U.S. Cl. CPC G09G 3/3659; G09G 3/3614; H01L 27/124; G09G 2300/0426; G09G 2300/0439; G09G 2300/0478; G09G 2300/0809

(57) ABSTRACT

A TFT array substrate is disclosed. The TFT array substrate includes a plurality of gate lines and a plurality of data lines, where the gate lines intersect with the data lines at a plurality of intersections, and where the gate lines and the data lines are separated by an insulator at each of the intersections. The TFT array substrate also includes a plurality of pixel units, disposed in an array, wherein the pixel units are defined by the intersections of the gate lines and the data lines. Each pixel unit includes a drain, a pixel electrode, and a common electrode, where the pixel electrode and the common electrode are configured to generate an electric field. In addition, the plurality of pixel units include a plurality of first pixel units and a plurality of second pixel units, and electric fields of two adjacent pixel units are opposite to each other in direction.

### CROSS-REFERENCES TO RELATED APPLICATIONS

This application claims the benefit of priority to Chinese Patent Application No. 201310754423.8, filed with the Chinese Patent Office on Dec. 31, 2013 and entitled “TFT ARRAY SUBSTRATE AND DISPLAY APPARATUS”, the content of which is incorporated herein by reference in its entirety.

### TECHNICAL FIELD

The present invention relates to the field of display technologies and particularly to a TFT array substrate and a display apparatus.

### BACKGROUND OF THE INVENTION

Thin Film Transistor (TFT) array substrates have been widely applied in display apparatuses, however in practice, the TFT array substrates and the display apparatuses suffer from the problem of a poor display effect or a degraded display quality.

### BRIEF SUMMARY OF THE INVENTION

One inventive aspect is a TFT array substrate. The TFT array substrate includes a plurality of gate lines and a plurality of data lines, where the gate lines intersect with the data lines at a plurality of intersections, and where the gate lines and the data lines are separated by an insulator at each of the intersections. The TFT array substrate also includes a plurality of pixel units, disposed in an array, wherein the pixel units are defined by the intersections of the gate lines and the data lines. Each pixel unit includes a drain, a pixel electrode, and a common electrode, where the pixel electrode and the common electrode are configured to generate an electric field. In addition, the plurality of pixel units include a plurality of first pixel units and a plurality of second pixel units, and electric fields of two adjacent pixel units are opposite to each other in direction.

Another inventive aspect is a display apparatus, including a TFT array substrate. The TFT array substrate includes a plurality of gate lines and a plurality of data lines, where the gate lines intersect with the data lines at a plurality of intersections, and where the gate lines and the data lines are separated by an insulator at each of the intersections. The TFT array substrate also includes a plurality of pixel units, disposed in an array, wherein the pixel units are defined by the intersections of the gate lines and the data lines. Each pixel unit includes a drain, a pixel electrode, and a common electrode, where the pixel electrode and the common electrode are configured to generate an electric field. In addition, the plurality of pixel units include a plurality of first pixel units and a plurality of second pixel units, and electric fields of two adjacent pixel units are opposite to each other in direction.

### BRIEF DESCRIPTION OF THE DRAWINGS

In order to make the technical solutions in the embodiments of the invention more apparent, the drawings to be used in a description of the embodiments will be briefly introduced below, and apparently the drawings to be described below are merely illustrative of some embodiments of the invention, and those ordinarily skilled in the art can derive from these drawings other drawings without any inventive effort. In the drawings:

FIG. 1 is a top view of first pixel units and second pixel units in an FFS-type TFT array substrate according to an embodiment of the invention;

FIG. 2(a) is a schematic structural diagram of a cross section along the line A-A′ in FIG. 1;

FIG. 2(b) is a schematic structural diagram of a cross section along the line B-B′ in FIG. 1;

FIG. 3(a) is an arrangement pattern of the first pixel units and the second pixel units according to an embodiment of the invention for frame-inversion;

FIG. 3(b), FIG. 3(d) and FIG. 3(e) are a correspondence relationship between the polarity of an operating voltage (i.e., the polarity of the non-inverted voltage) and the polarity of an electric field of a pixel unit (i.e., the polarity of the inverted voltage) in the case of inversion in the arrangement pattern in FIG. 3(a);

FIG. 3(c) is a comparative diagram of consecutive frames;

FIG. 4(a) is an arrangement pattern of the first pixel units and the second pixel units according to an embodiment of the invention for column-inversion;

FIG. 4(b), FIG. 4(c) and FIG. 4(d) are a correspondence relationship between the polarity of an input operating voltage (i.e., the polarity of the non-inverted voltage) and the polarity of an electric field of a pixel unit (i.e., the polarity of the inverted voltage) in the case of inversion in the arrangement pattern in FIG. 4(a);

FIG. 5 is a simplified top view of a first pixel unit and a second pixel unit in an IPS-type TFT array substrate according to an embodiment of the invention;

FIG. 6 is another schematic structural diagram of an electrode in the IPS-type TFT array substrate;

FIG. 7 is a schematic structural diagram of a cross section along the line C-C′ in FIG. 5;

FIG. 8 is a flow chart of steps in a method of manufacturing an FFS-type TFT array substrate in an example 1 according to an embodiment of the invention as shown in FIG. 1, FIG. 2(a) and FIG. (b);

FIG. 9(a), FIG. 10(a) and FIG. 11(a) are cross sectional views of respective step along the line A-A′ in FIG. 1;

FIG. 9(b), FIG. 10(b) and FIG. 11(b) are cross sectional views of respective step along the line B-B′ in FIG. 1;

FIG. 12(a) and FIG. 12(b) are schematic structural diagrams of a pixel unit in another process of manufacturing an FFS-type TFT array substrate according to an embodiment of the invention; and

FIG. 13 is a simplified diagram of a display apparatus according to an embodiment of the invention.

### DETAILED DESCRIPTION OF THE PREFERRED EMBODIMENTS

In order to make the objects, the technical solutions and the advantages of the invention more apparent, the invention will be further described in details with reference to the drawings. Apparently the described embodiments are only a part but all of the embodiments of the invention. Based upon the embodiments of the invention here, all of other embodiments derived by those ordinarily skilled in the art without any inventive effort shall come into the scope of the invention.

It shall be noted that in the embodiments of the invention, the “top” and the “bottom” are merely intended to suggest a relative positional relationship between a pixel electrode and a common electrode, for example, a pixel electrode at the top of a pixel unit means the pixel electrode above the common electrode; and in the embodiments of the invention, a “line” will not be limited only to a line of pixels corresponding to a gate line but can also be taken as x lines of pixels corresponding to x gate lines; and a “column” will not be limited only to a column of pixels corresponding to a data line but can also be taken as y columns of pixels corresponding to y data lines, where both x and y are positive integers.

It shall be noted that both the common electrode and the pixel electrode as referred to in the embodiments of the invention are made of a transparent conductive material, thickness and structure of the common electrode and the pixel electrode can be set dependent upon a particular demand for a display mode.

An embodiment of the invention provides a TFT array substrate including a plurality of gate lines and a plurality of data lines, where the gate lines insulatedly intersect with the data lines; and a plurality of pixel units disposed in an array, the pixel units are defined by the intersection of the gate lines and the data lines, and each pixel unit includes a drain, a pixel electrode and a common electrode, electric field is formed by the pixel electrode and the common electrode, the plurality of pixel units include a plurality of first pixel units and a plurality of second pixel units, and electric fields of two adjacent pixel units are opposite to each other in direction.

In the embodiment of the invention, there are a number of TFT array substrates which can be structured as described above including a TFT array substrate in the FFS mode, a TFT array substrate in the IPS mode, etc. The TFT array substrate in the FFS mode and the TFT array substrate in the IPS mode will be described below in details by way of particular examples thereof.

It shall be noted that a TFT in a TFT array substrate in operation may come with the phenomenon of leakage, and the phenomenon of leakage may be serious particularly with a TFT in a top-gate structure, because a gate of the TFT in the top-gate structure is disposed above a semiconductor layer, and the semiconductor layer is at the bottommost of the TFT, and when a backlight source starts to operate, the semiconductor layer will be illuminated directly by light, thus giving rise to significant optically-induced leakage current, and in the meantime, the semiconductor layer may be deteriorated, thus degrading an current conduction effect. Moreover the significant leakage current may also cause an increase in overall power consumption. Consequently it is not advisable to adopt the TFT in the top-gate structure for a pixel unit.

However it is not advisable either to alternately dispose a pixel unit with a TFT in the top-gate structure and a pixel unit, with a TFT in a bottom-gate structure, because leakage current in the TFT in the top-gate structure is far greater than the leakage current in the TFT in the bottom-gate structure in operation, and if both the pixel unit with a TFT in the top-gate structure and the pixel unit with a TFT in the bottom-gate structure are on a formed screen, then leakage current will differ across the respective pixel units on the whole screen, possibly by a difference value of 1000 times, and this difference in leakage current can not be uniformly compensated for, thus tending to result in a very poor display effect and display quality.

Both the TFT in the top-gate structure and the TFT in the bottom-gate structure may come with the phenomenon of leakage, but the TFT in the bottom-gate structure has less leakage current and is easy to fabricate in a process, so in order to improve a display effect and a display quality, a pixel unit with a TFT in the bottom-gate structure will be described as an example throughout the embodiments of the invention, although the invention will not be limited to the following embodiments.

The invention further provides an embodiment which is a TFT array substrate in the FFS mode (simply referred to as an FFS-type TFT array substrate).

In the FFS-type TFT array substrate, the pixel electrodes and the common electrodes are disposed at different layers, particularly as follows: in each first pixel unit, the common electrode is disposed above the pixel electrode, and the pixel electrode is electrically connected directly with the drain; and in each second pixel unit, the pixel electrode is disposed above the common electrode, and the pixel electrode is electrically connected with the drain through a first via hole in the second pixel unit. Thus the pixel electrode and the common electrode of each first pixel unit are opposite in location to the pixel electrode and the common electrode of each second pixel unit, thereby ensuring electric fields formed by the first pixel units to be opposite in direction to electric fields formed by the second pixel units when operating voltage at the same potential are input to the first pixel units and the second pixel units.

Further for the TFT array substrate inversion-driven in the form of frame-inversion (that is, the polarity of operating voltage input to the data lines are the same in a frame), the first pixel unit and the second pixel unit are disposed alternately along the direction of the data lines, and the first pixel unit and the second pixel unit are also disposed alternately along the direction of the gate lines. Signals applied to the data lines in two consecutive frames are signals inverse to each other, and the signal applied to all the data lines are the same in each frame.

Further for the TFT array substrate inversion-driven in the form of column-inversion (that is, operating voltages input to the adjacent data lines are opposite to each other in polarity in a frame), the first pixel unit and the second pixel unit are disposed alternately along the direction of the data lines, and two adjacent lines in the direction of the gate lines are one line of first pixel units and the other line of second pixel units. When a third signal is applied to the n-th data line, a fourth signal is applied to the (n+1)-th data line, where the third signal is inverse to the fourth signal, and n is a positive integer.

Further for the TFT array substrate inversion-driven in the form of line-inversion (that is, operating voltages (pixel voltages) of adjacent pixel lines are opposite to each other in polarity in a frame), the first pixel unit and the second pixel unit are disposed alternately along the direction of the gate lines, and two adjacent columns in the direction of the data lines are one column of first pixel units and the other column of second pixel units. When the m-th gate line is scanned, a first signal is applied to all the data lines; and when the (m+1)-th gate line is scanned, a second signal is applied to all the data lines, where the first signal is inverse to the second signal, and m is a positive integer.

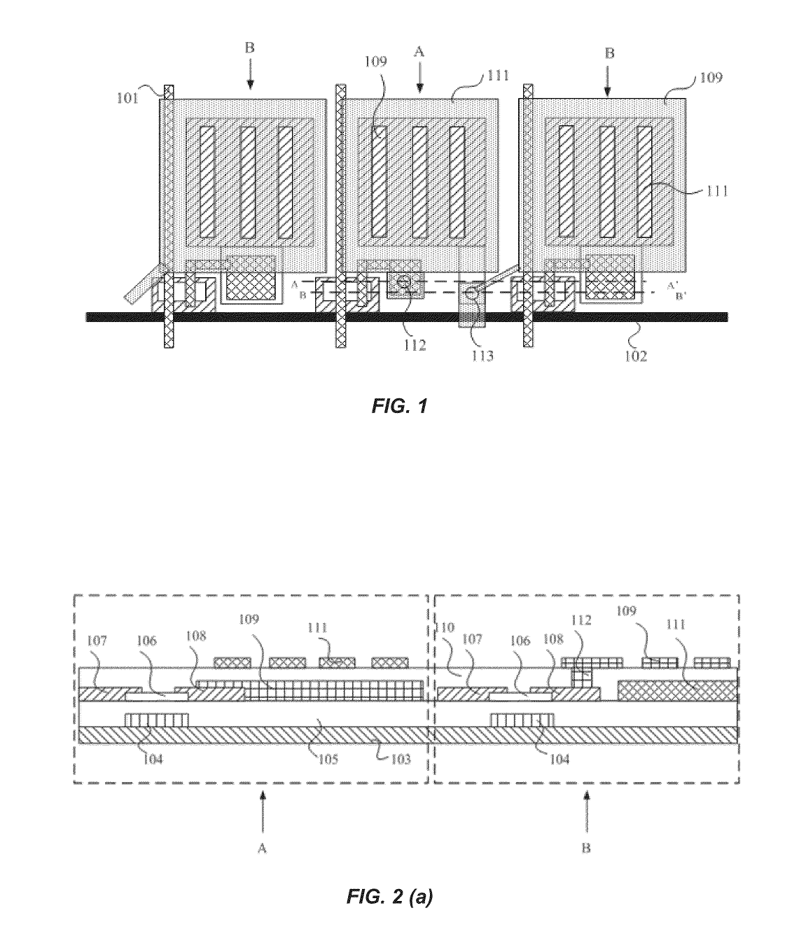

As illustrated in FIG. 1, there is illustrated a top view of first pixel units and second pixel units in an FFS-type TFT array substrate in an example 1 of the invention. In the TFT array substrate, there are three data lines 101 and a gate line 102 intersecting with the data lines 101 disposed on a substrate, and first pixel units A and second pixel units B defined by the intersection of the data lines 101 and the gate line 102, and FIG. 1 is merely a partial illustration instead of all the pixel units, and the other pixel units are structured similarly thereto, it shall be noted that the quantity of the data lines 101, the quantity of the gate line 102, the quantity of the first pixel units and the quantity of the second pixel units are just illustrated as examples but not limited thereto, and it shall be just met the condition that the TFT array substrate includes a plurality of gate lines and a plurality of data lines, the first pixel units and the second pixel units are defined by the intersection of data lines and the gate lines.

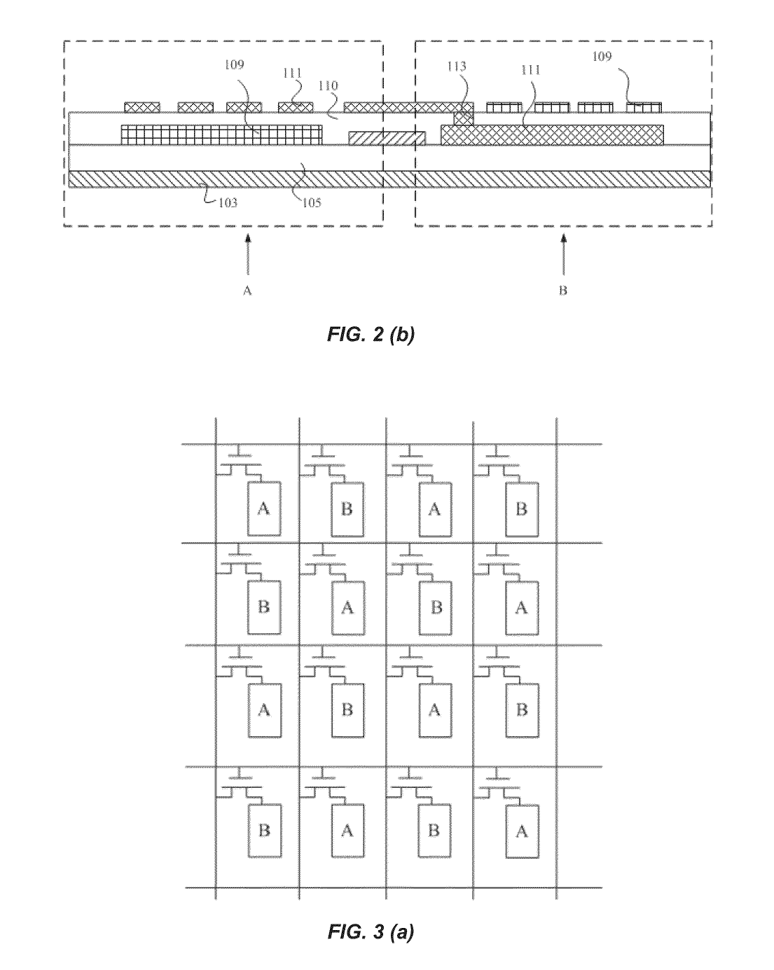

FIG. 2(a) is a schematic structural diagram of a cross section along the line A-A′ in FIG. 1, and FIG. 2(b) is a schematic structural diagram of a cross section along the line B-B′ in FIG. 1, referring to FIG. 1, FIG. 2(a) and FIG. 2(b), where the first pixel unit A includes the substrate 103, a gate line 102 extending in a horizontal direction, data lines 101 extends in a longitudinal direction, and a gate 104, a gate insulation layer 105, an active layer 106, a source 107, a drain 108, pixel electrodes 109, a passivation layer 110 and a common electrode 111 disposed on the substrate 103. The second pixel unit B includes the substrate 103, a gate line 102 extending in a horizontal direction, data lines 101 extends in a longitudinal direction, and the gate 104, the gate insulation layer 105, the active layer 106, the source 107, the drain 108, common electrodes 111, the passivation layer 110 and the pixel electrode 109 disposed on the substrate 103. As illustrated in FIG. 2(a), the pixel electrode 109 of the first pixel unit A is electrically connected with the drain 108 directly; and the pixel electrode 109 of the second pixel unit B is electrically connected with the drain 108 through a first via hole 112 in the passivation layer 110 of the second pixel unit B. As can be apparent from FIG. 2(b), the common electrode 111 of the first pixel unit A is electrically connected with the common electrode 111 of the second pixel unit B via a second via hole 113 in the passivation layer 110 of the second pixel unit B.

It shall be noted that at the connection via the second via hole, the common electrode 111 at the lower layer (bottom layer) in the second pixel unit B is not electrically connected with a common electrode line through the second via hole 113 but electrically connected with the common electrode 111 at the top layer in the first pixel unit A through the second via hole 113, because the common electrode line, which is usually made of metal, will block a part of light from being transmitted therethrough, thus reducing the transmittance at the second via hole 113. With the common electrode line at the second via hole replaced by the transparent common electrodes 111, all the common electrodes 111 on the TFT array substrate can be connected together with each other and finally with a common electrode line to thereby greatly improve an aperture ratio, where the common electrode line is located at the frame area of the TFT array substrate.

Further the common electrode 111 of the first pixel unit A are at the top layer in the first pixel unit, and the pixel electrode 109 of the second pixel unit B are at the top layer in the second pixel unit, and then the common electrode 111 of the first pixel unit A and the pixel electrode 109 of the second pixel unit B at the top layer are comb-shaped electrodes (i.e., the common electrode 111 of the first pixel unit A comprises slits, and the pixel electrode 109 of the second pixel unit B comprises slits); and the pixel electrode 109 of the first pixel unit A and the common electrode 111 of the second pixel unit B are typically planar electrodes (i.e., there is no slit in the pixel electrode 109 of the first pixel unit A, and there is no slit in the common electrode 111 of the second pixel unit B) or can also be comb-shaped electrodes as long as the pixel electrode 109 of the first pixel unit A is right under the slits of the common electrode 111 of the first pixel unit A and the pixel electrode 111 of the second pixel unit B is right under the slits of the pixel electrode 109 of the second pixel unit B. Stated otherwise, an electrode at the bottom layer of the pixel unit is right under the slit of an electrode at the top layer of the pixel unit.

In the TFT array substrate according to the embodiment of the invention, the first pixel units A and the second pixel units B can be disposed in different arrangement patterns for different inversion patterns.

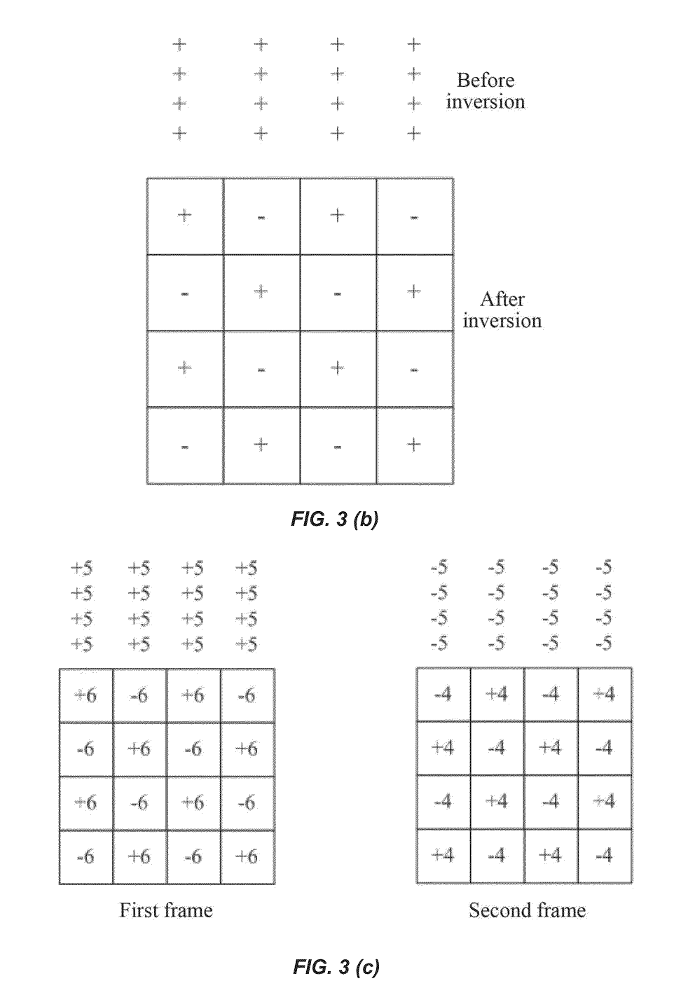

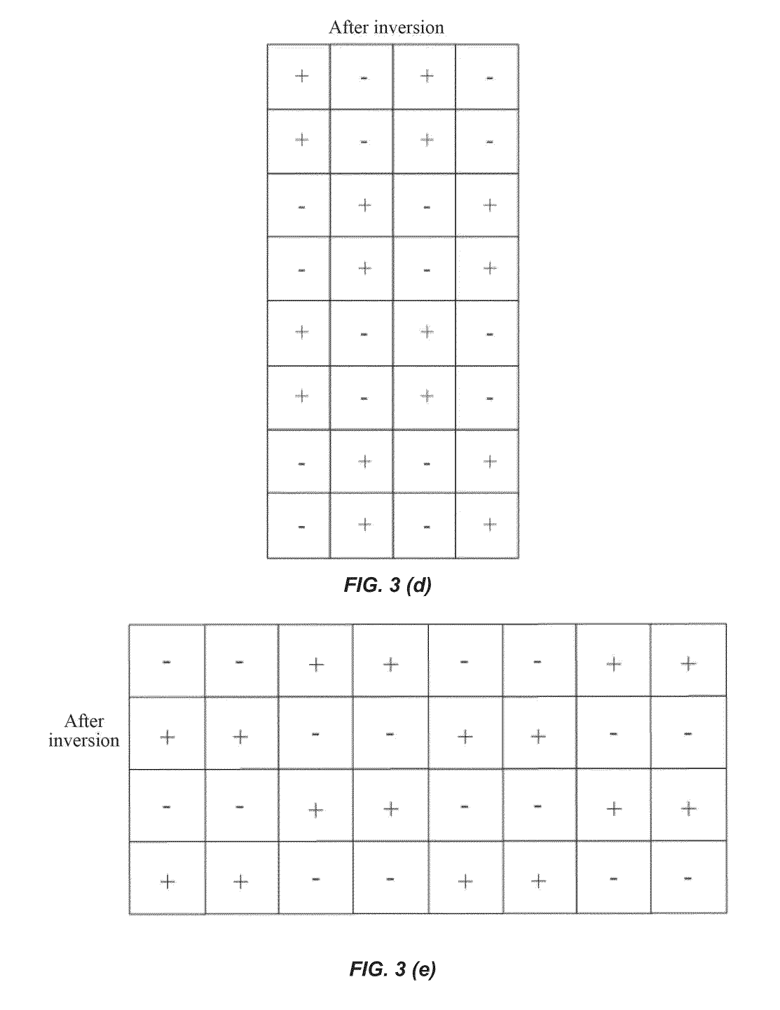

1. For frame-inverted driving, the first pixel units A and the second pixel units B are disposed in the pattern of a 4×4 matrix illustrated in FIG. 3(a).

When data signals of frame-inversion are input to the data lines, there will occur a correspondence relationship between the polarity of an operating voltage (i.e., the polarity of the non-inverted voltage) and the polarity of an electric field of a pixel unit (i.e., the polarity of the inverted voltage) as illustrated in FIG. 3(b), FIG. 3(d) and FIG. 3(e). The polarity inside a pixel unit is the polarity of an electric field of the pixel unit, and the polarity outside the pixel unit is the polarity of an operating voltage. It shall be noted here that since the common electrodes may come with a drift in potential (floating of potential), dot-inversion effect is not possibly performed by a frame-inversion in this arrangement pattern of the pixel units. For example, with a first frame (a preceding frame among two consecutive frames) and an input operating voltage of +5V, if the common electrodes drift in potential by −1V, then the electric fields of the respective pixel units are as illustrated in FIG. 3(c) on the left, and as can be apparent, the electric fields of the respective adjacent pixel units are opposite in direction but different in potential uniformly by 6V. With a second frame (a succeeding frame among the two consecutive frames) and an input operating voltage of −5V, if the common electrodes drift in potential still by −1V, then the electric fields of the respective pixel units are as illustrated in FIG. 3(c) on the right, where the electric fields of the respective adjacent pixel units are opposite in direction but uniformly different in potential by 4V. Although there are unequal differences in voltage in the two consecutive frames, the electric fields of the adjacent pixel units are opposite in direction in each frame to thereby improve a display effect and a display quality.

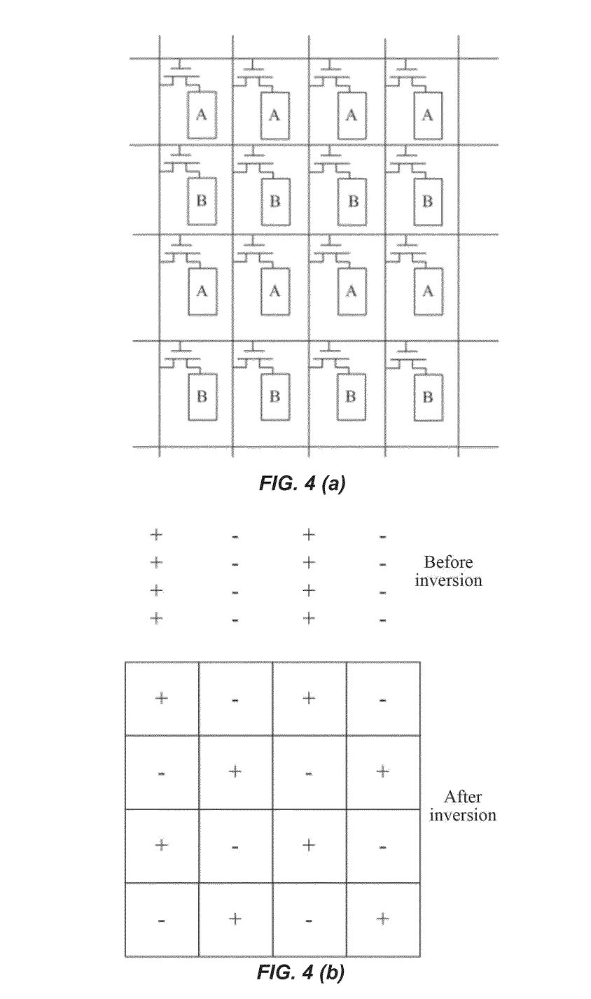

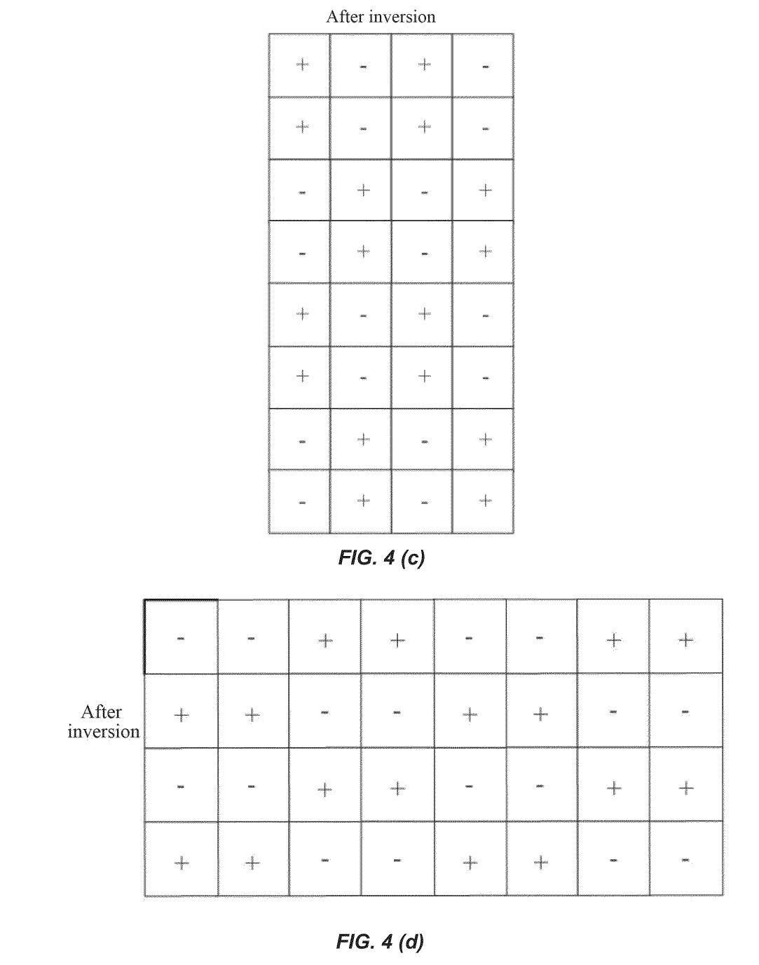

2. For column-inverted driving, the first pixel units A and the second pixel units B are disposed in the pattern of a 4×4 matrix illustrated in FIG. 4(a).

When data signals of column-inversion are input to the data lines, there will occur a correspondence relationship between the polarity of an operating voltage and the polarity of an electric field of a pixel unit as illustrated in FIG. 4(b). The polarity inside a pixel unit is the polarity of an electric field of the pixel unit, and the polarity outside the pixel unit is the polarity of an operating voltage. Similarly to the case of frame-inversion described above, the electric fields of the respective adjacent pixel units can be ensured to opposite in direction to thereby improve a display effect and a display quality in this embodiment.

Line-inversion is similar to column-inversion, and a repeated description thereof will be omitted here.

The invention further provides an embodiment which is a TFT array substrate in the IPS mode (simply referred to as an IPS-type TFT array substrate).

In the IPS-type TFT array substrate, the pixel electrode and the common electrode is disposed at the same layer, particularly as follows: in each first pixel unit, the common electrode and the pixel electrode are disposed in the same layer, a branch electrode of the common electrode and a branch electrode of the pixel electrode are disposed insulatedly and alternately; and in each second pixel unit, the common electrode and the pixel electrode are disposed in the same layer, a branch electrode of the common electrode and a branch electrode of the pixel electrode are disposed insulatedly and alternately, where each pixel electrode is electrically connected with the drain through a first via hole in each pixel unit. Thus the pixel electrode and the common electrode of each first pixel unit are opposite in location to the pixel electrode and the common electrode of each second pixel unit to thereby ensure electric fields formed by the first pixel units to be opposite in direction to electric fields formed by the second pixel units when operating voltage at the same potential are input to the first pixel units and the second pixel units.

Further for the TFT array substrate inversion-driven in the form of frame-inversion (that is, the polarities of operating voltage input to the data lines are the same in a frame), the first pixel units and the second pixel units are disposed alternately along the direction of the data lines, and the first pixel units and the second pixel units are also disposed alternately along the direction of the gate lines; and there are slits between the pixel electrodes of the first pixel units and the common electrodes of the second pixel units adjacent thereto on the left and on the right. Signals applied to the data lines in two consecutive frames are signals inverse to each other, and signals applied to all the data lines are the same in each frame.

Further for the TFT array substrate inversion-driven in the form of column-inversion (that is, operating voltages input to adjacent data lines are opposite in polarity in a frame), the first pixel units and the second pixel units are disposed alternately along the direction of the data lines; and two adjacent lines in the direction of the gate lines are one line of first pixel units and the other line of second pixel units, and there are slits between the first pixel units and the adjacent first pixel units and slits between the second pixel units and the adjacent second pixel units in the same line. When a third signal is applied to the n-th data line, a fourth signal is applied to the (n+1)-th data line, where the third signal is inverse to the fourth signal, and n is a positive integer.

Further for the TFT array substrate inversion-driven in the form of line-inversion (that is, operating voltages of each line are opposite in polarity in a frame), the first pixel units and the second pixel units are disposed alternately along the direction of the gate lines, and there are slits between the pixel electrodes of the first pixel units and the common electrodes of the second pixel units adjacent thereto on the left and on the right; and two adjacent columns in the direction of the data lines are one column of first pixel units and the other column of second pixel units. When the m-th gate line is scanned, a first signal is applied to all the data lines; and when the (m+1)-th gate line is scanned, a second signal is applied to all the data lines, where the first signal is inverse to the second signal, and m is a positive integer.

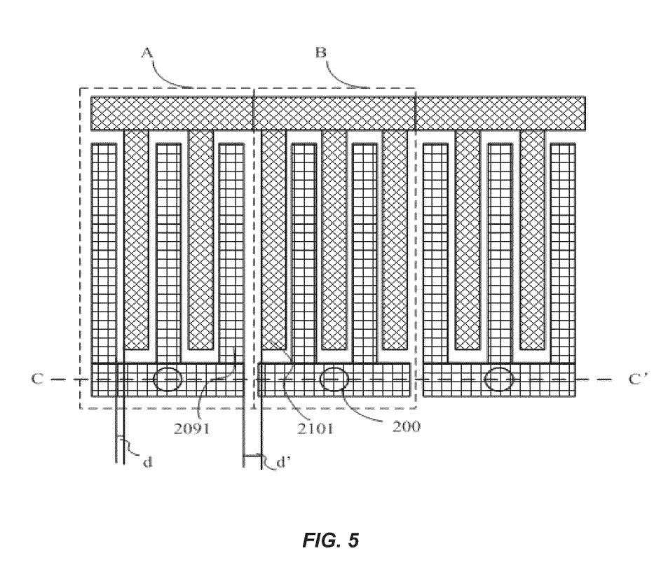

Specifically, as illustrated in FIG. 5, there is illustrated a simplified top view of a first pixel unit A and a second pixel unit B in an IPS-type TFT array substrate in an example 2 of the invention. Branch electrodes of each pixel electrode and branch electrodes of each common electrode are disposed alternately, and in each first pixel unit A, there are three branch electrodes 2091 of the pixel electrode and two branch electrodes 2101 of the common electrode, and the two branch electrodes 2101 of the common electrode are disposed insulatedly and respectively in slits between the branch electrodes 2091 of the pixel electrode; and there is a preset distance d between a branch electrode 2091 of a pixel electrode and q branch electrode 2101 of a common electrode adjacent thereto in each pixel unit. In each second pixel unit B, there are two branch electrodes 2091 of the pixel electrode and three branch electrodes 2101 of the common electrode, and the two branch electrodes 2091 of the pixel electrode are disposed insulatedly and respectively in slits between the respective branch electrodes 2101 of the common electrode. Particularly each pixel electrode is electrically connected with the drain through the first via hole 200 at its end electrodes, and end electrodes of the each common electrodes are electrically connected in direct contact to connect the each common electrodes together. For the first pixel unit A and the second pixel unit B, there is a slit d′ between the two adjacent pixel units, and the width of the slit d′ is not less than the specific distance d between a branch electrode 2091 of the pixel electrode and a branch electrode 2101 of the common electrode in each pixel unit.

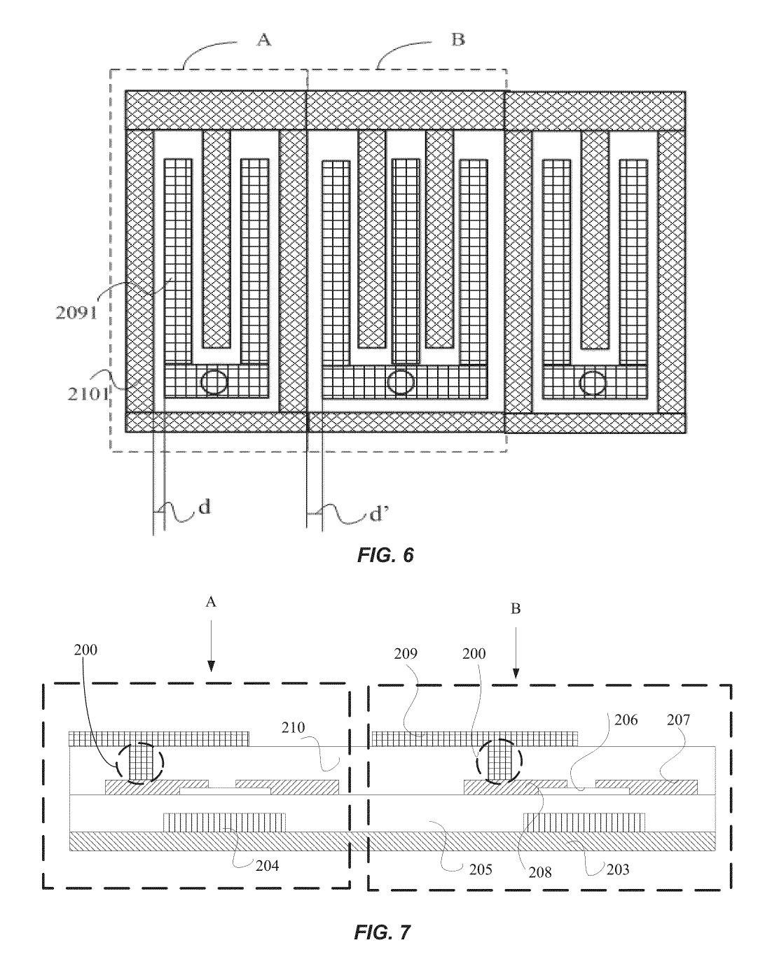

Moreover the electrodes in the first pixel unit A and the second pixel unit B can alternatively be as illustrated in FIG. 6. Similarly to FIG. 5, a difference is that in FIG. 6, there are two branch electrodes 2091 of the pixel electrode and three electrodes 2101 of the common electrode in each first pixel unit A, and there are three branch electrodes 2091 of the pixel electrode and two electrodes 2101 of the common electrode in each second pixel unit B. Moreover end electrodes are also disposed in the second pixel unit B, and the end electrodes of the second pixel unit B are connect to the branch electrodes of the common electrode in the second pixel unit, and the end electrodes of the second pixel unit B also are connected to the end electrodes of the adjacent first pixel unit.

FIG. 7 is a schematic structural diagram of a cross section along the line C-C′ in FIG. 5, referring to FIG. 5 and FIG. 7, where the first pixel unit A includes the substrate 203, and a gate 204, a gate insulation layer 205, an active layer 206, a source 207, a drain 208, a pixel electrode 209 and a common electrode above the substrate 203. The second pixel unit B includes the substrate 203, and the gate 204, the gate insulation layer 205, the active layer 206, the source 207, the drain 208, the common electrode and the pixel electrode 209 above the substrate 203. Particularly the pixel electrode 209 and the common electrode are disposed at the same layer in each pixel unit. As illustrated in FIG. 7, the pixel electrode 209 of the first pixel unit A is electrically connected with the drain 208 through a first via hole 200 in a passivation layer 210 of the first pixel unit A; and the pixel electrode 209 of the second pixel unit B is electrically connected with the drain 208 through the first via hole 200 in the passivation layer 210 of the second pixel unit B. And there is a slit d′ between adjacent pixel units.

In the TFT array substrate according to the embodiment of the invention, the first pixel units A and the second pixel units B can be disposed in different arrangement patterns for different inversion patterns.

1. For frame-inverted driving, the first pixel units A and the second pixel units B are disposed in the pattern of a 4×4 matrix illustrated in FIG. 3(a).

When data signals of frame-inversion are input to the data lines, there will occur a correspondence relationship between the polarity of an operating voltage and the polarity of an electric field of a pixel unit as illustrated in FIG. 3(b). The polarity inside a pixel unit is the polarity of an electric field of the pixel unit, and the polarity outside the pixel unit is the polarity of an operating voltage. It shall be noted here that similarly to the FFS-type TFT array substrate, the electric fields of the adjacent pixel units are opposite in direction in each frame in the IPS-type TFT array substrate to thereby improve a display effect and a display quality.

2. For column-inverted driving, the first pixel units A and the second pixel units B are disposed in the pattern of a 4×4 matrix illustrated in FIG. 4(a).

When data signals of column-inversion are input to the data lines, there will occur a correspondence relationship between the polarity of an operating voltage (i.e., the polarity of the non-inverted voltage) and the polarity of an electric field of a pixel unit (i.e., the polarity of the inverted voltage) as illustrated in FIG. 4(b) to FIG. 4(d). The polarity inside a pixel unit is the polarity of an electric field of the pixel unit, and the polarity outside the pixel unit is the polarity of an operating voltage. Similarly to the case of frame-inversion described above, the electric fields of the adjacent pixel units are opposite in direction to thereby improve a display effect and a display quality in this embodiment.

Line-inversion is similar thereto, and a repeated description thereof will be omitted here.

Further to the TFT array substrates according to the previous embodiments described above, embodiments of the invention further provide methods of manufacturing the TFT array substrate, where one embodiment primarily addresses a method of manufacturing the FFS-type TFT array substrate described in an embodiment as shown in FIG. 1, FIG. 2(a) and FIG. (b), and another embodiment briefly addresses a method of manufacturing the IPS-type TFT array substrate described in another embodiment as shown in FIG. 5, FIG. 6 and FIG. 7. The embodiments will be described below in details with reference to the drawings, but the invention will not be limited to the following embodiments.

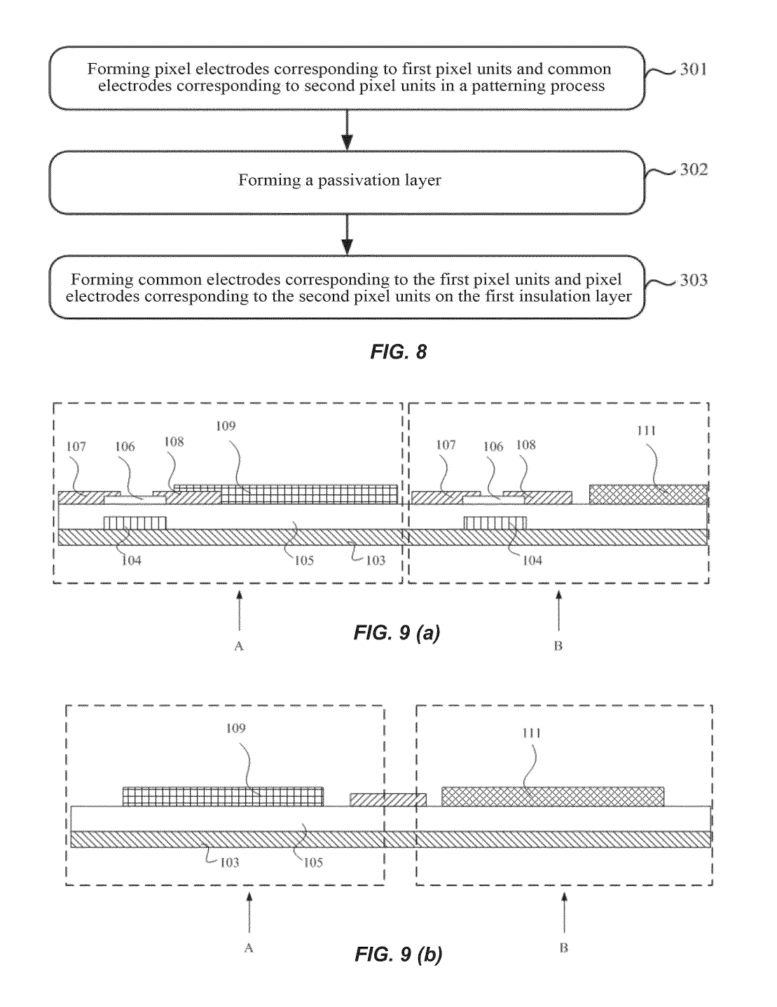

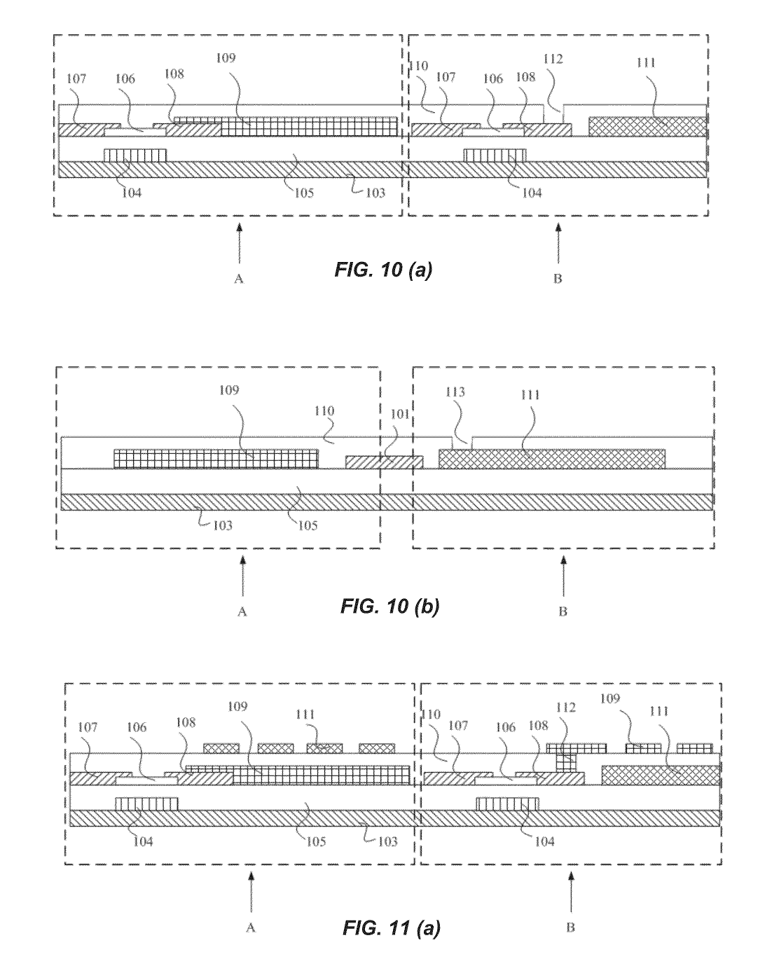

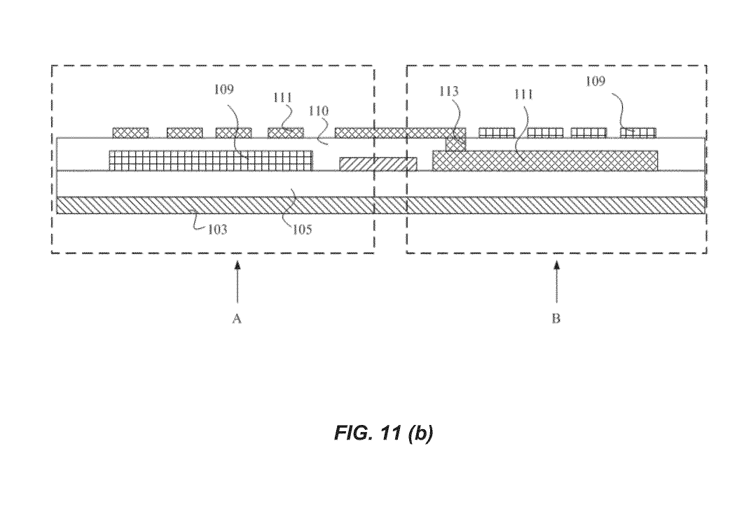

The invention further provides an embodiment, and as illustrated in FIG. 8, there is illustrated a flow chart of steps in a method, according to the embodiment of the invention, of manufacturing an FFS-type TFT array substrate according to an embodiment of the invention as shown in FIG. 1, FIG. 2(a) and FIG. (b), where the TFT array substrate includes the first pixel units A and the second pixel units B. Since the TFT array substrate is manufactured in a process involving particular operational means similar to the prior art, so only a brief description thereof will be given below. It shall be noted that FIG. 9(a), FIG. 10(a) and FIG. 11(a) are cross sectional views of respective step along the line A-A′ in FIG. 1, and FIG. 9(b), FIG. 10(b) and FIG. 11(b) are cross sectional views of respective step along the line B-B′ in FIG. 1. Particular steps of the method includes:

The step 301 is to form pixel electrodes corresponding to first pixel units and common electrodes corresponding to second pixel units in a patterning process.

As illustrated in FIG. 9(a), a transparent conductive material is deposited on a substrate with an array of TFTs formed thereon and then masked, exposed, etched, etc., to form the pixel electrodes 109 of the first pixel unit A and the common electrodes 111 of the second pixel units B. And a part of the pixel electrodes 109 of the first pixel unit A overlay the drains 108, so those pixel electrodes 109 are electrically connected directly with the drains 108.

As illustrated in FIG. 9(b), a transparent conductive material is deposited and then masked, exposed, etched, etc., to form the pixel electrodes 109 of the first pixel unit A and the common electrodes 111 of the second pixel units B. And the pixel electrodes 109 of the first pixel unit A and the common electrodes 111 of the second pixel units B are on both sides of the data lines 101 and insulated from the data lines.

The step 302 is to form a passivation layer.

As illustrated in FIG. 10(a), a passivation layer 110 is disposed above the formed pixel electrodes and common electrodes and etched to form first via holes 112 in the passivation layer 110 of the second pixel units B and to expose the drains 108 in second the pixel units B.

As illustrated in FIG. 10(b), a passivation layer 110 is formed, and then second via holes 113 are formed in the passivation layer 110 of the second pixel units B and a part of the common electrodes of the second pixel units B are exposed.

The step 303 is form common electrodes corresponding to the first pixel units and pixel electrodes corresponding to the second pixel units on the first insulation layer.

As illustrated in FIG. 11(a), a transparent conductive material is deposited and then masked, exposed, etched, etc., to form the common electrodes 111 of the first pixel units A and the pixel electrodes 109 of the second pixel units B, where the pixel electrodes 109 of the second pixel units B are electrically connected with the drains 108 via the first via holes 112.

As illustrated in FIG. 11(b), the common electrodes 111 of the first pixel units A and the pixel electrodes 109 of the second pixel units B are formed through deposition, and the common electrodes 111 of the first pixel units A are electrically connected with the pixel electrodes 109 of the second pixel units B via the second via holes 113. Since the second via holes 113 are not located at a common electrode line (common electrode line is made of metal and not transparent) but at the common electrodes (common electrodes are transparent), with all common electrodes can be connected together to the common electrode line in the frame area of the TFT array substrate, thus improving both the transmittance and the aperture rate of the pixel units.

Thus the structure as illustrated in FIG. 2 can be manufactured in the method of manufacturing a TFT array substrate described above so that the first pixel units A and the second pixel units B are disposed alternately along the direction of the data lines and also the first pixel units A and the second pixel units B are disposed alternately along the direction of the gate lines.

Alternatively the structure as illustrated in FIG. 3 can be manufactured where the first pixel units and the second pixel units are disposed alternately along the direction of the data lines, and two adjacent lines in the direction of the gate lines include one line of first pixel units and the other line of second pixel units.

An array substrate in which the first pixel units A and the second pixel units B disposed in a desirable pattern can be manufactured in the fabrication method described above, and the second via holes are disposed above the common electrodes of the second pixel units, the common electrodes of the first pixel units A are electrically connected with the common electrodes of the second pixel units through the second via holes without disposing a common electrode line in a display area, thereby avoiding the problem of a lower aperture ratio and improving the transmittance and the aperture rate of the pixel units.

Further to the foregoing manufacturing method, the invention can further improve an aperture ratio by adjusting the order of the steps in the fabrication process for an improved structure.

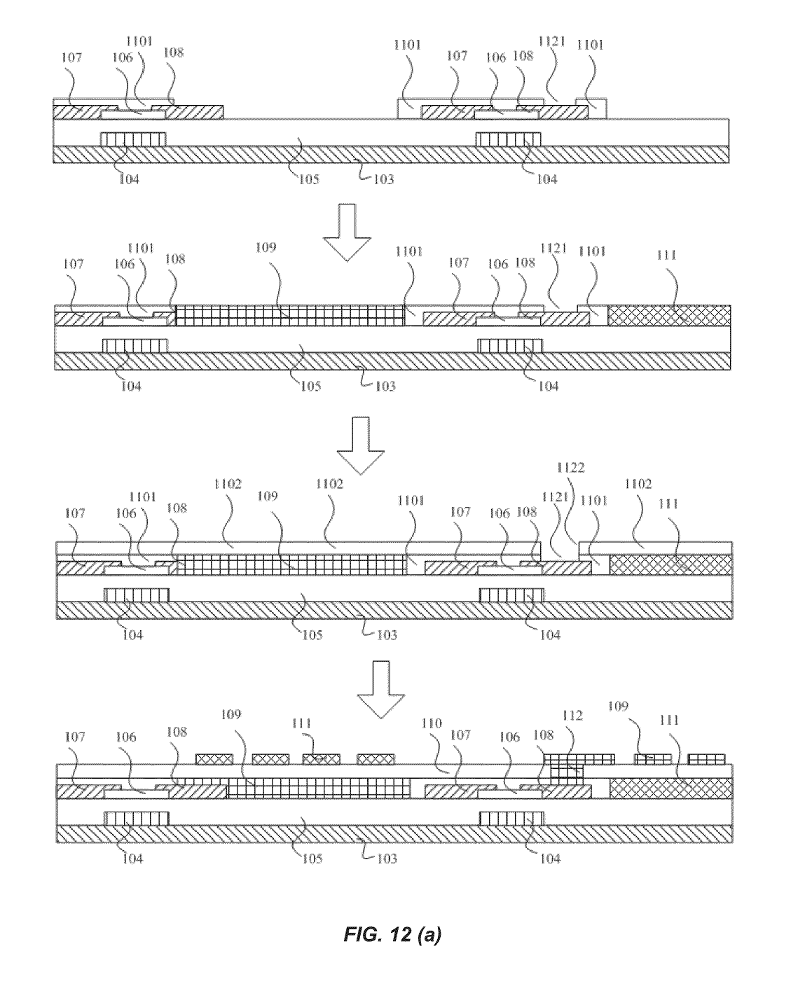

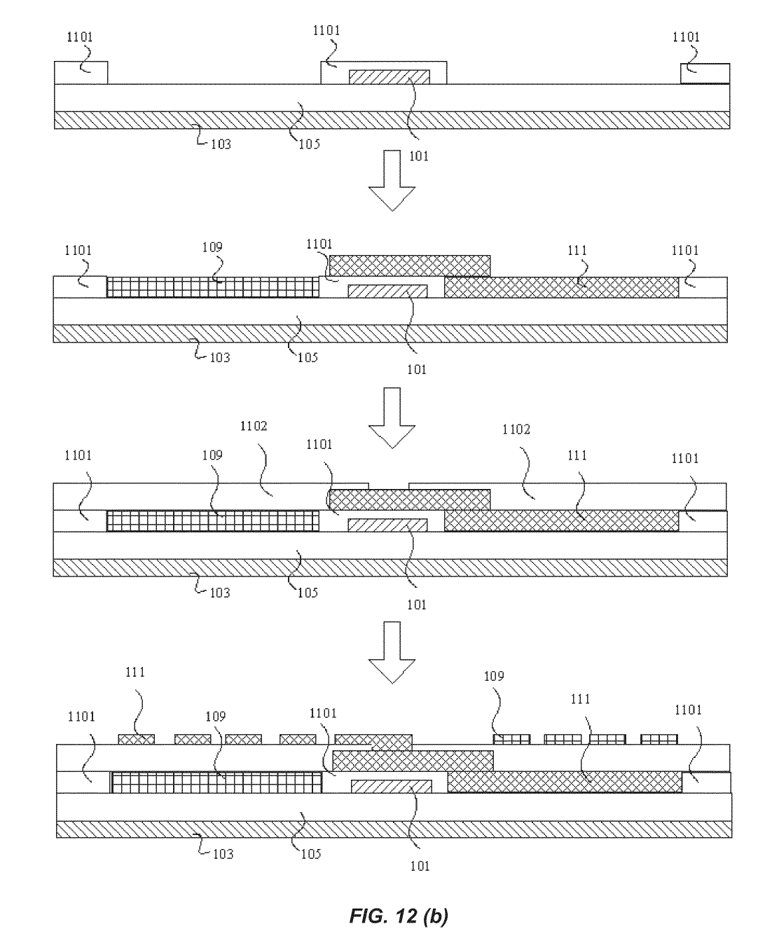

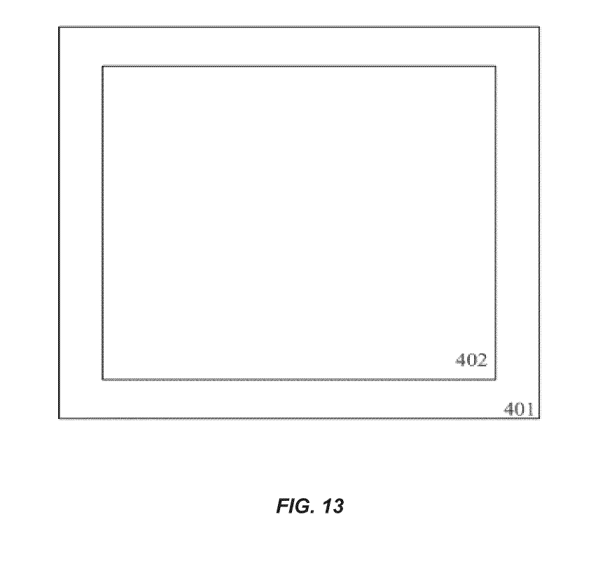

As illustrated in FIG. 12(a) and FIG. 13(b), particular steps are as follows:

Firstly a first passivation layer 1101 is formed on a prepared array of TFTs and etched for the locations of the pixel electrodes 109 of the first pixel units A and the common electrodes 111 of the second pixel units B while forming the first via holes 1121 in the second pixel units B.

Secondly a transparent conductive material is deposited to form the pixel electrodes 109 of the first pixel units A and the common electrodes 111 of the second pixel units B as in the second step illustrated in FIG. 12(a). Also a common electrode bridge 114 is disposed above the common electrodes 111 of the second pixel units B and the data lines 101 to be electrically connected directly with the common electrodes 111 of the second pixel units B and insulated from the data lines 101 by the first passivation layer 1101 as illustrated in FIG. 12(b), where the common electrode bridge 114 is also of a transparent conductive material.

Thirdly a second passivation layer 1102 is formed and the first via holes 1122 are formed at the locations of the first via holes 1121 as in the third step illustrated in FIG. 12(a). Also the second via holes 113 are disposed above the common electrode bridge 114 formed in the second step, and preferably the projections of the second via holes 113 on the substrate 103 are encompassed by the projections of the data lines 101 on the substrate 103.

Fourthly a transparent conductive material is deposited to form the common electrodes 111 of the first pixel units A and the pixel electrodes 109 of the second pixel units B. Also the common electrodes 111 of the first pixel units A are electrically connected directly with the pixel electrodes 109 of the second pixel units B through the second via holes 113 and the common electrode bridge 114.

Thus there is a cross sectional view of the TFT array substrate in the fourth step as illustrated in FIG. 12(b), and as can be apparent from the figure, the second via holes 113 are disposed above the data lines in this example unlike the second via holes 113 disposed above the common electrodes of the second pixel units B in the previous example, and since a black matrix must be disposed above the data lines, it will be not necessary to dispose a black matrix for the second via holes 113, and the disposition of a black matrix for the second via holes 113 and the data lines 101 will suffice. Thus this example can still further improve an aperture ratio over the step 301 to the step 303.

The invention further provides an embodiment of a method of manufacturing an IPS-type TFT substrate, and since steps in a method of manufacturing an IPS-type TFT substrate are similar to the steps in the method of manufacturing an FFS-type TFT substrate and the first pixel units and the second pixel units are disposed in the two array substrates under the same principle, a repeated description of those points common to the previous embodiment will be omitted here, and a difference of the two embodiments is that the IPS-type TFT substrate is manufactured by forming the pixel electrodes and the common electrodes of the first pixel units simultaneously with the pixel electrodes and the common electrodes of the second pixel units (i.e., the pixel electrodes and the common electrodes of the first pixel units, and the pixel electrodes and the common electrodes of the second pixel units are formed in a same step).

As illustrated in FIG. 13, an embodiment of the invention further provides a display apparatus 401 including a TFT array substrate 402, where the TFT array substrate 402 can be any of the TFT array substrates according to the embodiments of the invention mentioned above.

Although the preferred embodiments of the invention have been described, those skilled in the art benefiting from the underlying inventive concept can make additional modifications and variations to these embodiments. Therefore the appended claims are intended to be construed as encompassing the preferred embodiments and all the modifications and variations coming into the scope of the invention.

Evidently those skilled in the art can make various modifications and variations to the invention without departing from the spirit and scope of the invention. Thus the invention is also intended to encompass these modifications and variations thereto so long as the modifications and variations come into the scope of the claims appended to the invention and their equivalents.

What is claimed is:

1. A TFT array substrate, comprising:
a plurality of gate lines and a plurality of data lines, wherein the gate lines intersect with the data lines at a plurality of intersections, wherein the gate lines and the data lines are separated by an insulator at each of the intersections; and
a plurality of pixel units disposed in an array, wherein the pixel units are defined by the intersections of the gate lines and the data lines, wherein each pixel unit comprises:
a drain,
a pixel electrode, and
a common electrode,
wherein the pixel electrode and the common electrode are configured to generate an electric field,
wherein the plurality of pixel units comprise a plurality of first pixel units and a plurality of second pixel units, and
wherein electric fields of two adjacent pixel units are opposite to each other in direction.

2. The TFT array substrate according to claim 1, wherein:
in each first pixel unit:
the common electrode is disposed above the pixel electrode with respect to a substrate, and the pixel electrode is electrically connected with the drain, and
in each second pixel unit:
the pixel electrode is disposed above the common electrode with respect to the substrate, and the pixel electrode is electrically connected with the drain through a first via hole in the second pixel unit.

3. The TFT array substrate according to claim 2, wherein:
the first pixel units and the second pixel units are disposed alternately along the direction of the data lines, and two adjacent lines of pixel units in the direction of the gate lines comprise one line of first pixel units and another line of second pixel units.

4. The TFT array substrate according to claim 2, wherein:
the first pixel units and the second pixel units are disposed alternately along the direction of the gate lines, and two adjacent columns of pixel units in the direction of the data lines comprise one column of first pixel units and another column of second pixel units.

5. The TFT array substrate according to claim 2, wherein:
the first pixel units and the second pixel units are disposed alternately along the direction of the data lines, and the first pixel units and the second pixel units are also disposed alternately along the direction of the gate lines.

6. The TFT array substrate according to claim 2, wherein:
in each first pixel unit, the common electrode is electrically connected with the common electrode in the second pixel unit through a second via hole in the second pixel unit.

7. The TFT array substrate according to claim 1, wherein,
in each first pixel unit:
the common electrode and the pixel electrode are disposed in the same layer, and
a branch electrode of the common electrode and a branch electrode of the pixel electrode are disposed alternately, and are insulated from one another; and
in each second pixel unit;
the common electrode and the pixel electrode are disposed in the same layer, and
a branch electrode of the common electrode and a branch electrode of the pixel electrode are disposed alternately, and are insulated from one another, and
wherein each pixel electrode is electrically connected with the drain through a first via hole in each pixel unit, and a slit is disposed between the first pixel unit and the second pixel unit adjacent to each other.

8. The TFT array substrate according to claim 7, wherein:
the first pixel units and the second pixel units are disposed alternately along the direction of the data lines, and two adjacent lines of pixel units in the direction of the gate lines comprise one line of first pixel units and another line of second pixel units.

9. The TFT array substrate according to claim 7, wherein:
the first pixel units and the second pixel units are disposed alternately along the direction of the gate lines, and two adjacent columns of pixel units in the direction of the data lines comprise one column of first pixel units and another column of second pixel units.

10. The TFT array substrate according to claim 7, wherein:
the first pixel units and the second pixel units are disposed alternately along the direction of the data lines, and the first pixel units and the second pixels unit are also disposed alternately along the direction of the gate lines.

11. The TFT array substrate according to claim 3, configured such that:
when the m-th gate line is scanned, a first signal is applied to all the data lines; and
when the (m+1)-th gate line is scanned, a second signal is applied to all the data lines,
wherein the first signal is an inverse signal of the second signal, and m is a positive integer.

12. The TFT array substrate according to claim 4, configured such that:
a third signal is applied to the n-th data line; and
a fourth signal is applied to the (n+1)-th data line, wherein the third signal is an inverse signal of the fourth signal, and n is a positive integer.

13. The TFT array substrate according to claim 5, configured such that:
signals applied to the data lines in two consecutive frames are inverse to each other, and signals applied to all the data lines are the same in each frame.

14. The TFT array substrate according to claim 7, wherein the width of the slit is not less than the distance between the branch electrode of the pixel electrode and the branch electrode of the common electrode adjacent thereto in each pixel unit.

15. The TFT array substrate according to claim 8, configured such that:
when the m-th gate line is scanned, a first signal is applied to all the data lines; and
when the (m+1)-th gate line is scanned, a second signal is applied to all the data lines,
wherein the first signal is an inverse signal of the second signal, and m is a positive integer.

16. The TFT array substrate according to claim 9, configured such that:
a third signal is applied to the n-th data line; and
a fourth signal is applied to the (n+1)-th data line,
wherein the third signal is an inverse signal of the fourth signal, and n is a positive integer.

17. The TFT array substrate according to claim 10, configured such that:
signals applied to the data lines in two consecutive frames are inverse to each other, and signals applied to all the data lines are the same in each frame.

18. The TFT array substrate according to claim 3, in each first pixel unit, the common electrode is electrically connected with the common electrode in the second pixel unit through a second via hole in the second pixel unit.

19. The TFT array substrate according to claim 4, in each first pixel unit, the common electrode is electrically connected with the common electrode in the second pixel unit through a second via hole in the second pixel unit.

20. A display apparatus, comprising a TFT array substrate, the TFT array substrate, comprising:
a plurality of gate lines and a plurality of data lines, wherein the gate lines intersect with the data lines at a plurality of intersections, wherein the gate lines and the data lines are separated by an insulator at each of the intersections; and
a plurality of pixel units disposed in an array, wherein the pixel units are defined by the intersections of the gate lines and the data lines, wherein each pixel unit comprises:
a drain,
a pixel electrode, and
a common electrode,
wherein the pixel electrode and the common electrode are configured to generate an electric field,
wherein the plurality of pixel units comprise a plurality of first pixel units and a plurality of second pixel units, and
wherein electric fields of two adjacent pixel units are opposite to each other in direction.
